(19) United States
(12) Patent Application Publication
(10) Pub. No.: US 2021/0123849 A1
(43) Pub. Date: Apr. 29, 2021

(54) METHODS AND DEVICES FOR MEMS BASED PARTICULATE MATTER SENSORS

(71) Applicants: NAVPREET SINGH, MONTREAL (CA); MOHANNAD ELSAYED, VERDUN (CA); MOURAD EL-GAMAL, BROSSARD (CA)

(72) Inventors: NAVPREET SINGH, MONTREAL (CA); MOHANNAD ELSAYED, VERDUN (CA); MOURAD EL-GAMAL, BROSSARD (CA)

(21) Appl. No.: 17/082,330

(22) Filed: Oct. 28, 2020

Related U.S. Application Data
(60) Provisional application No. 62/926,668, filed on Oct. 28, 2019.

(51) Int. Cl. G01N 15/02; H01L 41/113; H01L 41/04

(52) U.S. Cl. CPC G01N 15/0255; G01N 2015/0261; H01L 41/04; H01L 41/1132

(57) ABSTRACT

Airborne pollutants from natural and man-made sources are an increasing where their aerodynamic properties determine how far into the human respiratory system they penetrate. International and national guidelines or regulatory limits specify limits for particulate matter (PM) at different particulate dimensions leading to a requirement for low cost compact PM detectors/sensors. A flow of known and desired size particles are separated and guided by a virtual impactor towards a microelectromechanical systems (MEMS) sensor, e.g. MEMS resonator, yielding the required PM detectors/sensors. Further, in conjunction with the virtual impactor and MEMS sensor additional elements are provided to exploit thermophoresis or di-electrophoresis such that the particles within the sensing area of the MEMS sensor can be removed. Accordingly, the MEMS sensor based particle detector/sensor can be periodically reset allowing for extended operational life of the MEMS sensor based particle detector/sensor and/or enhanced performance over extended periods.

### CROSS-REFERENCE TO RELATED APPLICATIONS

This patent application claims the benefit of priority from U.S. Provisional patent application 62/926,668 filed Oct. 28, 2019 entitled “Methods and Devices for MEMS based Particulate Matter Sensors”, the entire contents of which are incorporated herein by reference.

### FIELD OF THE INVENTION

This patent application relates to microelectromechanical systems (MEMS) and more particularly to MEMS devices for particle detector sensors.

### BACKGROUND OF THE INVENTION

The increase in the amount of airborne pollutants is a rising concern in developed as well as developing countries. These airborne particles consist of natural and man-made sources. Their aerodynamic properties determine how far they can get into the human respiratory system. The World Health Organization (WHO) sets limits on the amount of particulate matter (PM) that a human body can tolerate without risking respiratory or cardiovascular diseases. This limit is 10 μg/m³ annual mean and 25 μg/m³ daily mean for PM2.5 (particles of diameter 2.5 μm or less) and 20 μg/m³ annual mean and 50 μg/m³ daily mean for PM10 (particles of 10 μm diameter or less). This necessitates the need for developing methods to measure the PM present in the air.

There are broadly two categories of consumer instruments available to monitor the PM in the air. The first category is based on gravimetric methods of directly measuring the mass of the particles. The particles are collected on a filter over a fixed period of time and are then weighed in a laboratory. These methods are expensive which, in conjunction with their size, limit their widespread usage. The second type of monitors are based on the principle of light scattering. In these sensors, the particles are illuminated with light of a certain wavelength and the amount of the scattered light gives an approximation of the number of particles. These sensors make several assumptions to estimate the density and the size distribution of the particles, leading to inaccurate results. As these sensors are based on sophisticated optical elements, they are also relatively expensive although smaller than the gravimetric based instruments. Their cost and complicated use also mean that these are not generally deployed. As such PM monitoring is not common within most environments the general population live and work in, being limited to national survey/monitoring or annual quality checks on air conditioning systems etc.

However, recent advances in the field of microelectromechanical systems (MEMS) have resulted in the use of MEMS resonators to measure the amount of gases and particulate matter in the air. A resonating structure, such as a cantilever, a surface acoustic wave resonator (SAW resonator or SAWR), or a capacitive micromachined ultrasonic transducer (CMUT) have been used as a microscopic weighing scale which, on deposition of mass on the sensing area, can register a shift in the resonant frequency or the phase of a signal. Although these implementations could help overcome the challenges of size and cost, they have failed to make it into commercial products due to issues related to not being able to clear the sensing elements from particles after each measurement, and the general lack of specific particle size distinction.

Accordingly, it would be beneficial to provide an overall solution compatible with high volume fabrication processes in order to reduce the size and cost of PM detectors/sensors. Accordingly, the inventors have established a novel PM detector/sensor which exploits a sensor based upon a piezoelectric resonator fabricated using a commercial multi-user MEMS process in conjunction with a micro virtual impactor to segregate the particles based upon their size and inertia imparted from an air flow through the particle detector/sensor. Accordingly, a flow of a known and desired size, e.g. PM2.5, can be separated and guided towards the sensing MEMS resonator. Further, the inventors have integrated in conjunction with the virtual impactor and MEMS resonator additional elements which exploit the principles of thermophoresis or di-electrophoresis to clear the particles from the sensing area of the MEMS resonator. This mechanism will force the particles towards and away from the sensing resonator based on a temperature or potential gradient. Accordingly, the MEMS resonator based particle detector/sensor can be periodically reset allowing for extended operational life of the MEMS resonator based particle detector/sensor and/or enhanced performance over extended periods.

Other aspects and features of the present invention will become apparent to those ordinarily skilled in the art upon review of the following description of specific embodiments of the invention in conjunction with the accompanying figures.

### SUMMARY OF THE INVENTION

It is an object of the present invention to mitigate limitations within the prior art relating to particle detectors through the use of microelectromechanical systems (MEMS) resonators and more particularly to MEMS resonator devices for particle detector sensors.

In accordance with an embodiment of the invention there is provided a method of detecting particles comprising:
providing a microelectromechanical systems (MEMS) resonator comprising a membrane, a piezoelectric layer atop the membrane, an electrode atop the piezoelectric layer and at least one anchor;
exposing the MEMS resonator to a source of particles; and
determining in dependence upon a shift in a characteristic of the MEMS resonator a mass of particles deposited upon the membrane; wherein
the MEMS resonator is piezoelectrically driven;
a metal layer is patterned on top of the piezoelectric layer to act as the top electrode, while the substrate acts as the bottom electrode (ground plane).

In accordance with an embodiment of the invention there is provided a device comprising:
a filter for providing a source of particles having a predetermined maximum dimension;
a sensor comprising at least a microelectromechanical systems (MEMS) resonator; and
a first electrical circuit for driving the MEMS resonator; and
a second electrical circuit for determining a characteristic of the MEMS resonator.

In accordance with an embodiment of the invention there is provided a device comprising:
a microelectromechanical systems (MEMS) resonator comprising a membrane, a piezoelectric layer atop the membrane, an electrode atop the piezoelectric layer and at least a pair of anchors; wherein
the MEMS resonator is piezoelectrically driven;
a metal layer is patterned on top of the piezoelectric layer to act as the top electrode, while the substrate acts as the bottom electrode (ground plane).

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts an exemplary configuration of a virtual impactor for directing particles of a known or desired size towards a sensor;

FIG. 2 depicts a microelectromechanical systems (MEMS) resonator within the sensing region of a virtual impactor such as depicted in FIG. 1;

FIG. 3 depicts a MEMS resonator such as may be employed for particle sensing according to embodiments of the invention such as may be employed within a virtual impactor as depicted in FIG. 1;

FIG. 4 depicts a configuration of a MEMS resonator in conjunction with thermophoretic plates according to an embodiment for resetting a MEMS resonator based particle sensor/counter such as may be employed within a virtual impactor such as depicted in FIG. 1;

FIG. 5 depicts a schematic of an exemplary simplified fabrication process for forming a MEMS resonator according to embodiments of the invention and as employed within particle counter sensors and/or particle detector sensors according to embodiments of the invention;

FIG. 6 depicts a schematic of an exemplary particle counter sensor and/or particle detector sensor according to embodiments of the invention employing a MEMS resonator according to embodiments of the invention;

FIG. 7 depicts schematically a finite element modelling simulation of a virtual impactor according to an embodiment of the invention with a reduced angle of intersection of the smaller and larger particle channels than that depicted within the virtual impactor of FIG. 1;

FIGS. 8A and 8B depict scanning electron microscope images of a MEMS resonator according to an embodiment of the invention and as employed within particle detector sensors according to embodiments of the invention;

FIG. 9 depicts the simulated resonant frequency shift of a MEMS resonator according to the design depicted in FIGS. 8A and 8B as a function of loading mass upon the MEMS resonator membrane;

FIG. 10 depicts the simulated resonance mode shape of the MEMS resonator of FIGS. 8A and 8B respectively;

FIG. 11 depicts the measured resonant frequency for a MEMS resonator according to the design depicted in FIGS. 8A and 8B with no loading mass upon the MEMS resonator membrane;

FIG. 12 depicts the measured electrical scattering parameter (S-parameter) for a MEMS resonator according to the design depicted in FIGS. 8A and 8B as function of time where the MEMS resonator is exposed to a stream of particulates; and

FIG. 13 depicts the measured resonant frequency for a MEMS resonator according to the design depicted in FIGS. 8A and 8B as function of time where the MEMS resonator is exposed to a stream of particulates.

### DETAILED DESCRIPTION

The present description is directed to microelectromechanical systems (MEMS) resonators and more particularly to MEMS resonator devices for particle detector sensors.

The ensuing description provides representative embodiment(s) only, and is not intended to limit the scope, applicability, or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional element.

In order to address the requirements for a compact low cost particle detector and/particle sensor whether employed in monitoring particulates generally or specifically compliance etc. with PM regulations such as those defined by the WHO etc. as noted above it would be beneficial to provide an overall solution compatible with high volume fabrication processes in order to reduce the size and cost of PM detectors/sensors.

Accordingly, the inventors have established a novel particle detector/sensor which exploits a sensor based upon a piezoelectric resonator fabricated using a commercial multi-user MEMS process in conjunction with a micro virtual impactor to segregate the particles based upon their size and inertia imparted from an air flow through the particle detector/sensor. Accordingly, a flow of a known and desired size, e.g. PM2.5, can be separated and guides towards the sensing MEMS resonator. Further, the inventors have integrated in conjunction with the virtual impactor and MEMS resonator additional elements which exploit the principles of thermophoresis or di-electrophoresis to clear the particles from the sensing area of the MEMS resonator. This mechanism can force the particles towards and away from the sensing resonator based on a temperature or potential gradient. Accordingly, the MEMS resonator based particle detector/sensor can be periodically reset allowing for extended operational life of the MEMS resonator based particle detector/sensor and/or enhanced performance over extended periods.

The MEMS resonator established by the inventors employs piezoelectric transduction in the MEMS resonator employed as the sensing element as this offers several advantages compared to other transduction schemes, e.g. capacitive transducers. Specifically, it has higher electromechanical coupling, thus leading to lower impedance levels, and imposes less geometrical constraints on the release of the resonating membrane, since a lower electrode is not needed. Further, it does not require a large biasing voltage thereby simplifying the design of the interfacing electronics and facilitating its deployment in portable devices, e.g. particle detectors/sensors for personal health monitoring etc. However, it would be evident that other embodiments of the invention may use other MEMS resonator structures including other MEMS membrane based resonators, MEMS beam based resonators, etc. exploiting other transduction techniques including, but not limited to, those employing capacitive based transduction.

The initial prototype particle detector/sensor employing a MEMS resonator in conjunction with the virtual impactor, fan etc. measures approximately 20 mm×20 mm×15 mm (approximately 0.8 inch×0.8 inch×0.6 inch) which the inventors believe is one of the smallest implementations of a self-contained particle detector/sensor reported to date. A limiting size factor for this particle detector sensor (PDS) according to an embodiment of the invention exploiting a MEMS sensor is the size of the fan integrated within the system to provide the air flow. Accordingly, a reduction of the footprint of the fan or its elimination from the PDS would provide for smaller footprints.

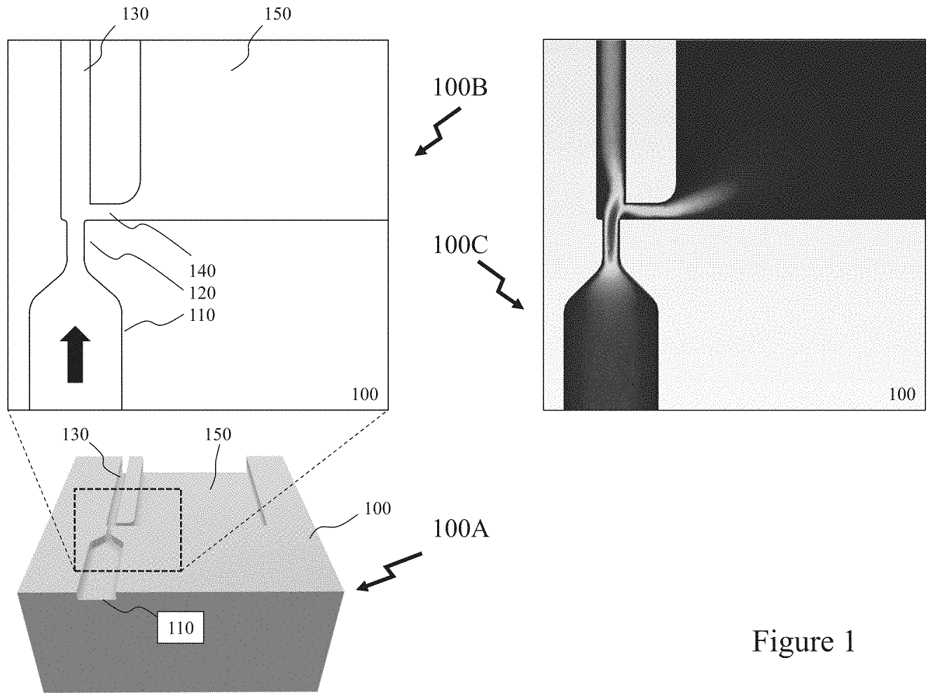

The concepts described and depicted below in respect of FIGS. 1 to 14 whilst being directed to a single MEMS resonator sensor within a sensing region which receives filtered particulates to meet PM 2.5 through the design of the virtual impactor may be configured for other discrete measurements, e.g. PM 10, or employed in series/parallel with other elements to perform multiple concurrent measurements.

Referring to FIG. 1 there is depicted an exemplary configuration of a virtual impactor for directing particles of a known or desired size towards a sensor within a particle detector sensor (PDS) according to an embodiment of the invention. Referring to first image 100A there is depicted a three-dimensional schematic of a virtual impactor-sensor chamber (VISC) structure 100 according to an embodiment of the invention wherein an inlet port 110, outlet channel 130 and sensor chamber 150 are depicted formed within the surface of a substrate. Second image 100B depicts a plan view of the VISC structure 100 wherein there is depicted the inlet port 110 which receives an airflow from an ambient environment being monitored and/or sampled where this airflow may be generated by a fan either pushing air into the VISC structure 100 or pulling air into the VISC structure 100. This fan may be part of the PDS, e.g. within a discrete personal health monitoring device, or external to the PDS, e.g. a fan within an air conditioning system which the PDS is associated with.

As depicted the airflow within the inlet port 110 of the VISC structure 100 enters a restricted region 120 before entering a region comprising the outlet channel 130 and impactor arm 140. The impactor arm 140 coupling to a sensing chamber 150. Third image 100C depicts a computer simulation of the VISC structure 100 wherein the particle density is depicted. By appropriate design of the restricted region 120, outlet channel 130, and impactor arm 140 then particulates below a specific maximum particle size may be filtered selectively into the impactor arm 140 and therein to the sensor chamber 150.

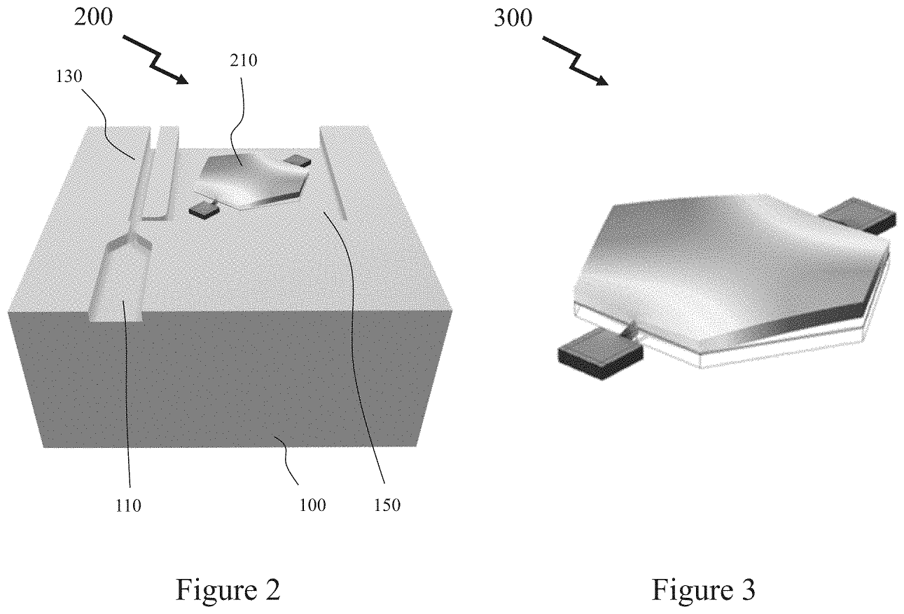

Now referring to FIG. 2 there is depicted a microelectromechanical systems (MEMS) resonator 210 within the sensing chamber (region) 150 of a virtual impactor—sensor chamber (VISC) structure 100 such as depicted in FIG. 1. As depicted the inlet port 110, outlet channel 130 and sensor chamber 150 are depicted formed within the surface of a substrate with the MEMS resonator 210 integrated within the sensor chamber 150. As will be described subsequently according to the selection of the substrate the MEMS resonator 210 may be monolithically integrated into the VISC structure 100 or it may be hybrid integrated into the VISC structure 100.

Referring to FIG. 3 there is depicted a MEMS resonator 300 such as may be employed for PDS according to embodiments of the invention such as may be employed within a VISC structure, such as VISC structure 100 as depicted in FIGS. 1 and 2 respectively. As described below the resonant frequency of the MEMS resonator 300 will reduce as particulates/particles deposit upon the upper surface of the MEMS resonator 300 loading it with a mass. This shift in the resonant frequency can be electrically measured through electrical scattering parameters (S-parameters) of an electrical circuit comprising the MEMS resonator 300 allowing the increased mass resulting from particulate/particle deposition to be determined/monitored. As depicted in FIG. 2 the MEMS resonator 210, for example MEMS resonator 300 in FIG. 3, is deployed within a sensor chamber 150 which receives via the VISC structure particles below a predetermined dimension determined by the design of the VISC structure.

However, it would be evident that over time the mass upon the MEMS resonator within a PDS would increase continuously with exposure to particulates/particles. At some point the loaded mass will increase suppressing the resonator's resonance or reducing it to a point outside the detectable range of the associated monitoring electrical circuit even where the airflow into the sensing chamber comprising the MEMS resonator is expelled outside the PDS. These representing two possible scenarios where the increasing mass limits the lifetime. This may be acceptable in applications where the PDS is a single-use/disposable PDS. However, in applications where the PDS is required to have an extended lifetime beyond these limits then it would be beneficial for the PDS to include a mechanism for “resetting” the sensor which may be either after each measurement, after a predetermined period of time, or after a predetermined mass is measured for example.

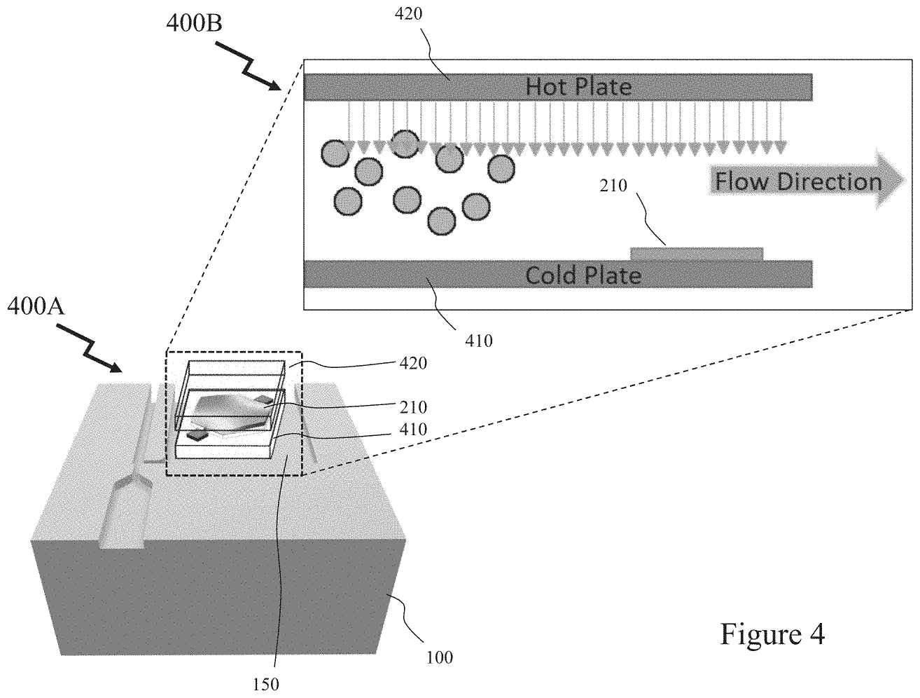

Now referring to FIG. 4 there is depicted a configuration of a MEMS resonator in conjunction with thermophoretic plates according to an embodiment for resetting a MEMS resonator based particle sensor such as may be employed within a virtual impactor such as depicted in FIG. 1. Accordingly, as depicted in FIG. 4 in three-dimensional (3D) perspective image 400A a MEMS resonator 210 is deployed within the sensor chamber 150 of the VISC structure 100 where the MEMS resonator 210 is between a lower (cold) plate 410 and upper (hot) plate 420. The lower (cold) plate 410 and upper (hot) plate 420 providing a pair of thermophoretic plates where these allow for forcing particles/particulates away from the MEMS resonator and back into the airflow through the sensing chamber allowing for the PDS to be reset. The thermophoretic plates exploit thermophoresis (also known as thermomigration, thermodiffusion, the Soret effect, or the Ludwig-Soret effect) wherein different particle types exhibit different responses to the force of a temperature gradient. The terms “hot” and “cold” being relative to the ambient temperature of the sensing chamber within the VISC structure 100. It would be also evident that these terms apply during the period when the pair of thermophoretic plates are active during a “cleaning” or reset process within the PDS.

Alternatively, within another embodiment of the invention according to the ambient environment of the particulates/particles being detected/monitored or the characteristics of the particulates/particles the plates may be reversed such that the MEMS resonator 210 is disposed upon a lower hot plate with an upper cold plate. Alternatively, the lower plate and upper plate may be dielectrophoresis (DEP) electrodes allowing for the generation of an electrostatic field within the sensing chamber allowing for exploitation of the dielectrophoresis (DEP) effect wherein a force is exerted on a dielectric particle when it is subjected to a non-uniform electric field. Beneficially, DEP does not require the particle to be charged.

Accordingly, particulate filtering via a VISC structure such as VISC structure 100, a particle detector such as MEMS resonator 300 in FIG. 3, and plate structure comprising lower plate 410 and upper plate 420 as depicted in FIG. 4 provides for a compact particle detector and/or particle detector core according to embodiments of the invention for a PDS according to an embodiment of the invention. Within other embodiments of the invention only a single upper plate, e.g. upper plate 420, may be employed where the electrode and/or membrane of the MEMS resonator are employed as the lower plate rather than providing a discrete lower plate, e.g. lower plate 410.

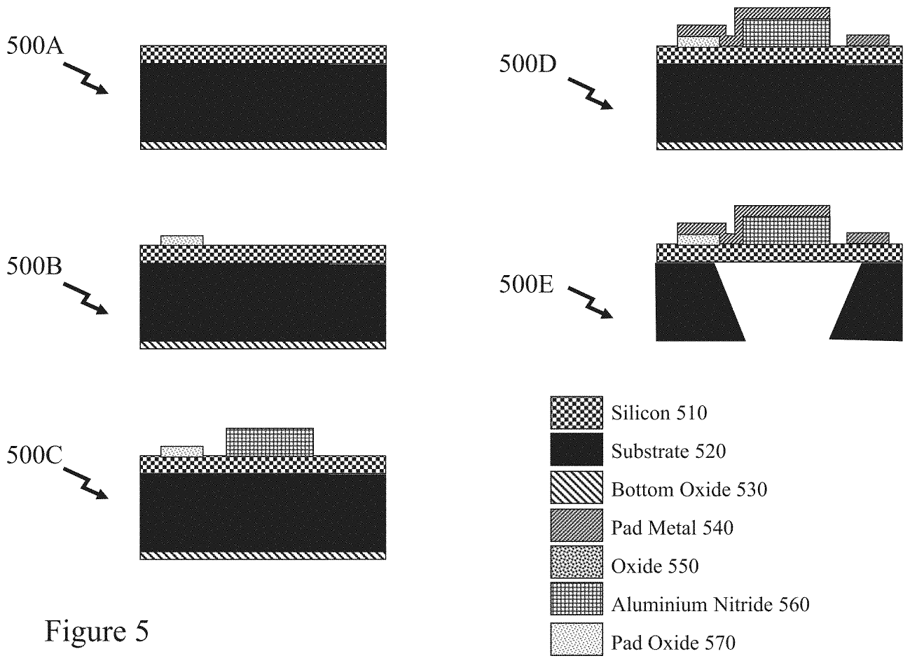

Referring to FIG. 5 there is depicted a schematic of an exemplary simplified fabrication process for forming a MEMS resonator according to embodiments of the invention and as employed within particle counter sensors and/or particle detector sensors according to embodiments of the invention. Accordingly, referring to first image 500A in a first step a silicon layer (silicon 510) is deposited atop onto a substrate 520 which has a back coating, comprising bottom oxide 530. Next in the second step, as depicted in second image 500B, a pad, comprising pad oxide 570 is deposited and patterned. Subsequently in a third step, depicted in third image 500C, a piezoelectrical layer, comprising aluminum nitride 560, is deposited and patterned. The aluminum nitride 560 providing the piezoelectric material for piezoelectric actuation of the MEMS resonator which has the silicon layer as its membrane.

Subsequently in a fourth step, depicted in fourth image 500D, a metallization, comprising pad metal 540, is deposited and patterned to form a bond pad atop the pad and connect to the piezoelectric layer allowing for electrical connection of the piezoelectric actuation layer to the external control circuitry. Finally, in fifth step, depicted in fifth image 500E the back coating, comprising bottom oxide 530, is patterned to allow etching of the substrate 520 beneath the silicon layer (silicon 510) releasing the membrane of the MEMS resonator, and then finally removed.

It would be evident to one of skill in the art that other process flows may be employed to form the MEMS resonator, that other materials other than silicon may be employed to form the membrane of the MEMS resonator, that other materials other than aluminum nitride may be employed to provide the piezoelectric layer, and other designs for the MEMS resonator may be employed. For example, a MEMS resonator compatible with a commercial PiezoMUMPs foundry process as described and depicted in “Bulk Mode Disk Resonator with Transverse Piezoelectric Actuation and Electrostatic Tuning” (Elsayed et al., J. Microelectromechanical Systems. Syst., Vol. 25, pp. 252-261, April 2016). Also, transduction mechanisms other than piezoelectric may be employed, e.g. electrostatic, piezoresistive, etc.

A MEMS resonator as described and depicted in respect of FIGS. 2-5 for integration with a VISC structure forming part of a PDS according to embodiments of the invention and described above may be monolithically or hybridly integrated within the sensor chamber.

With monolithic integration, for example, within an embodiment of the invention the substrate of the VISC structure 100 may be the substrate 520 of the MEMS resonator as described and depicted in FIG. 5 such that the MEMS resonator may be formed upon the substrate. The input port 110, restricted region 120, outlet channel 130, impactor arm 140, and sensing chamber 150 of the VISC structure 100 may be formed by depositing and patterning a material such as polyimide, polydimethylsiloxane (PMDS), a spin-on-glass (SOG) etc. Alternatively, these may be formed within a second substrate which is flipped onto the substrate comprising the MEMS resonator.

With hybrid integration, for example, within an embodiment of the invention the MEMS resonator may be formed as a discrete die, mounted onto the substrate of the VISC structure, and electrically connected to pads formed upon the substrate of the VISC structure. For example, the substrate of the VISC structure may be PMDS, a thiol-ene polymers such as OSTEmer™, and SU8 photoresist either discretely or upon a carrier such as silicon, glass, ceramic, plastic etc.

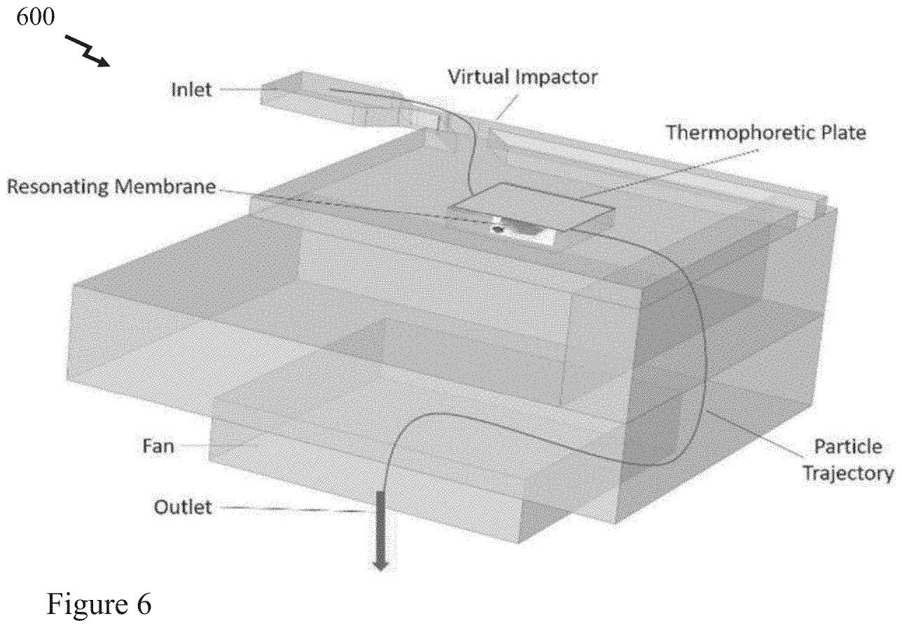

Referring to FIG. 6 there is depicted a schematic 600 of a PDS according to an embodiment of the invention consisting of three parts:
a sensing unit, MEMS resonator;
a virtual impactor-sensor chamber (VISC); and
a thermophoretic plate and/or DEP electrodes.

A fan is depicted in schematic 600 pulling air through the PDS although within other embodiments of the invention a fan may push air through the PDS. The VISC directs particles of a known/desired size towards the sensing unit which comprises the MEMS resonator. As noted above the third part uses a thermophoretic plate (and/or DEP electrodes) which can force the particles from the VISC towards and away from the sensing unit. For example, during a measurement phase the thermophoretic plate (and/or DEP electrodes) may direct particles to the MEMS resonator whilst in a cleaning phase the thermophoretic plate (and/or DEP electrodes) may direct the particles away from the MEMS resonator allowing them to be swept out by the net airflow. As noted, the thermophoretic plate (and/or DEP electrodes) allow for resetting of the sensor, i.e. to clear the particles from the sensor after the measurements have been made.

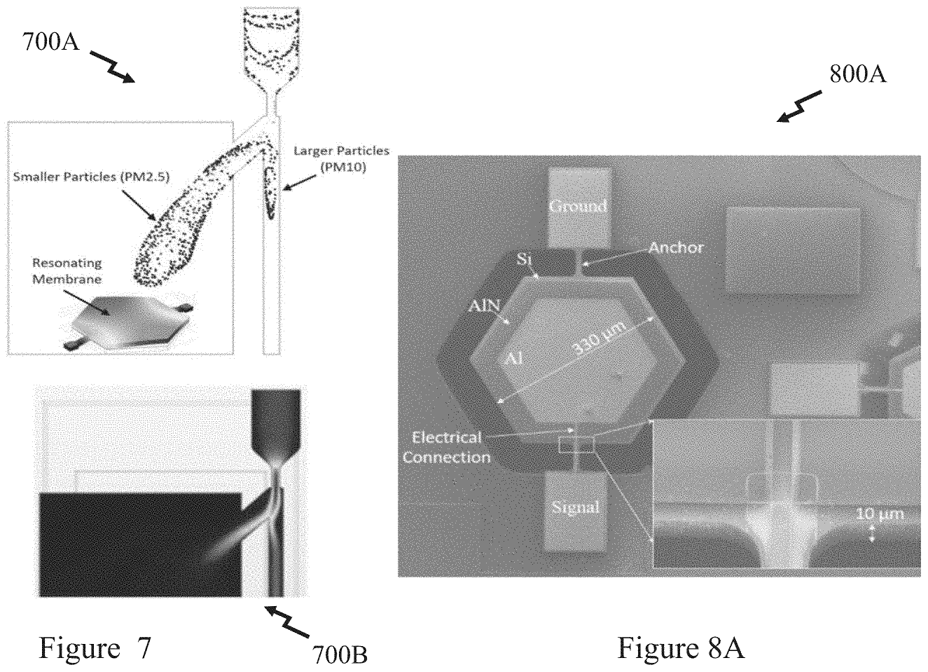

Referring to FIG. 7 there is depicted schematically a virtual impactor (VI) according to an embodiment of the invention with a reduced angle of intersection of the smaller and larger particle channels than that depicted within the virtual impactor of FIG. 1. Within FIG. 7 trajectories of simulated segregated particles are depicted in first image 700A whilst a Finite Element Modelling (FEM) simulation of the velocity profile of the VI is depicted in second image 700B. The VIs depicted in FIG. 1 and FIG. 7 distinguishes between the particle's sizes based on their inertia. The VI in FIG. 7 was designed to separate particles 2.5 μm and smaller from the incoming particles, i.e. the VI supports a PDS for PM2.5 measurements.

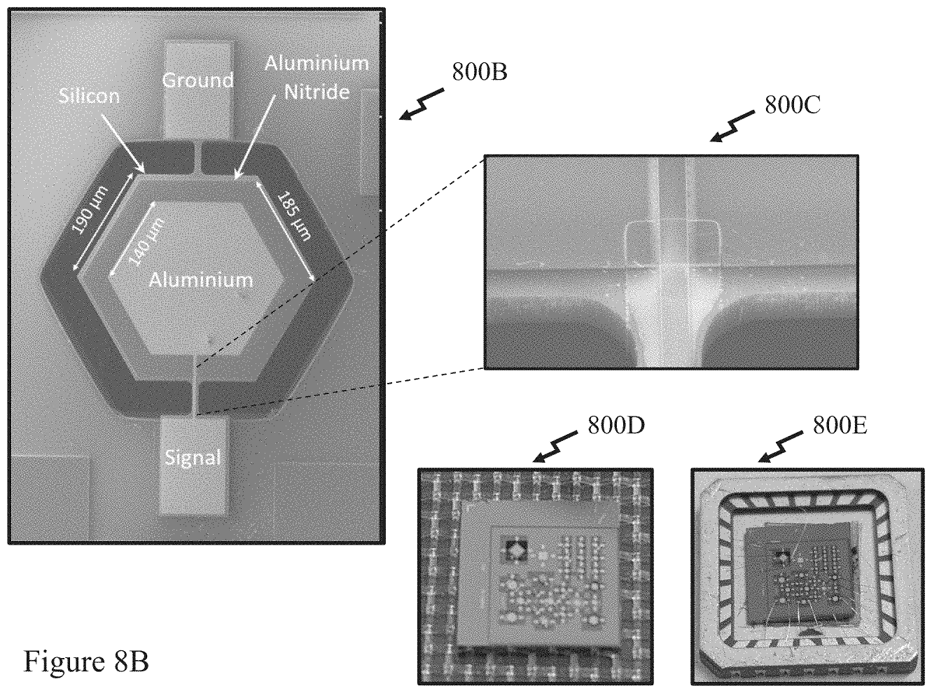

The transduction principle of the MEMS resonator is the mass loading effect, i.e. an addition of a mass to the membrane results in a shift in its resonant frequency. The main component of the resonator is a micromachined silicon plate, for a MEMS resonator such as described and depicted in FIG. 5, or another membrane such as silicon dioxide, silicon nitride, silicon oxynitride, carbon, aluminum oxide, silicon carbide, or another ceramic. Referring to FIG. 8A there is depicted a scanning electron micrograph (SEM) of a fabricated MEMS resonator according to an embodiment of the invention. As depicted the membrane of the MEMS resonator is hexagonal although within other embodiments of the invention the resonator may take other shapes, e.g., polygonal with any number of sides circular, or be a cantilever. It may employ flexural modes, as here, or other modes such as bulk modes. The membrane is coupled via a pair of anchors one of which provides a ground signal connection to the membrane whilst the other provides a signal connection. Optionally, within other embodiments of the invention the membrane may be coupled via four anchors or more, for example a circular membrane with four anchors such as taught by Elsayed et al.

The resonant frequency, f, of the membrane can be determined from Equations (1) and (2) where a is the resonance mode constant, A, D and t are the area, the flexural rigidity, and the thickness of the resonating plate, respectively, p is the plate's effective density, E is the effective Young's modulus of the structural material of the membrane, and v is the Poisson's ratio of the structural material of the membrane.

$$\begin{matrix}f = \frac{\frac{α}{2 A} \sqrt{D}}{ρ t} & ( 1 ) \\ D = \frac{{Et}^{3}}{12 ( 1 - {v}^{2} )} & ( 2 ) \\ Δ f = \frac{- 2 {f}^{2} Δ m}{2 A \sqrt{ρ} μ} & ( 3 )\end{matrix}$$

The Sauerbrey equation describes the relationship between the resonant frequency shift of a resonator and the mass change of the resonator membrane. This is given by Equation (3) where Δf is the change in the resonant frequency resulting from mass loading, Δm is the mass change and μ is the shear modulus of the membrane (e.g. silicon (Si)). The inventors designed the MEMS resonator depicted in FIGS. 8A and 8B to have a shift of ˜1 kHz in the resonant frequency on the deposition of 0.01 μg of mass on the resonating membrane. Accordingly, the MEMS resonators were fabricated using the commercial multi-user foundry process PiezoMUMPs. A simplified schematic of the process flow being described and depicted above in respect of FIG. 5.

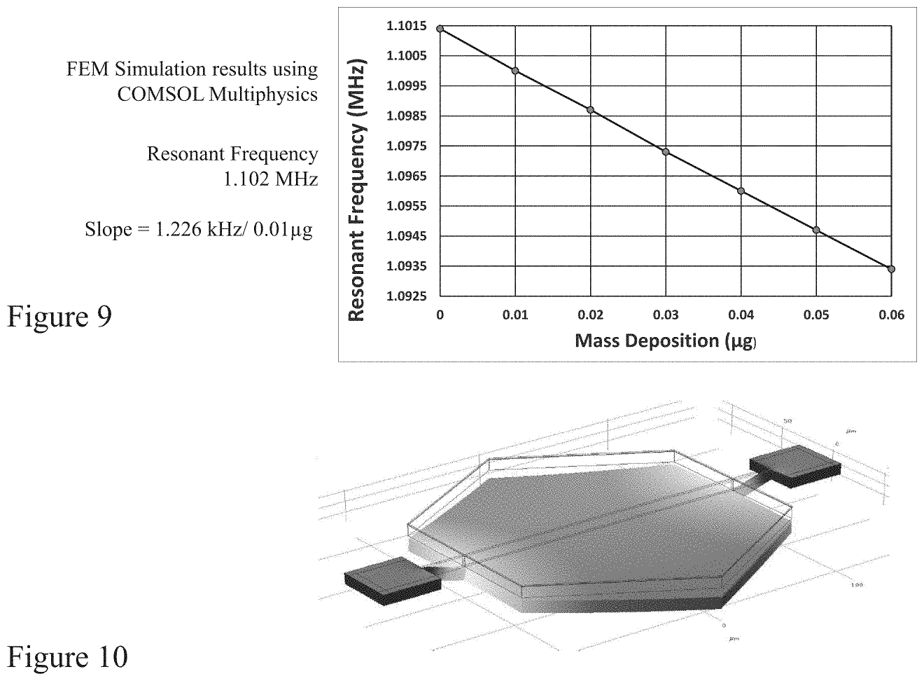

Referring to FIG. 8B in first image 800B the resonator consists of a 10 μm thick silicon (Si) hexagonal membrane, with each side measuring 190 μm with an anchor (Si) of length and width of 60 μm and 9 μm, respectively. A hexagonal aluminium nitride layer 0.5 μm thick with 185 μm side length, was then deposited on top of this silicon membrane. Subsequently, this was covered with a hexagonal shaped 1 μm thick aluminium (Al) electrode of side 140 μm to connect to the signal pad for transduction. The ground being provided via the silicon membrane directly. The Al pad (140 μm×100 μm) on the signal side was isolated from the ground using a 1 μm thick silicon oxide layer. The anchor at the signal side being depicted in the SEM image in second image 800C. Third image 800D depicts an as fabricated test die, whilst fourth image 800E depicts the fabricated test die bonded into an LCC-28 package for testing. The Finite Element Modelling (FEM) simulations of the resonator depicted in FIGS. 8A and 8B were performed using the COMSOL Multiphysics software. Using a method similar to that described within Elsayed et al. “Piezoelectric Bulk Microdisk Resonator Post-Processed for Enhanced Quality Factor Performance” (J. Micoelectromechanical Systems, Vol. 26, pp. 75-83) the inventors performed a parametric sweep to find the length and width of the anchors, in order to reduce the anchor losses, and obtain the dimensions of the resonator. The simulations gave an eigenfrequency of 1.102 MHz with a mass sensitivity of 1.226 kHz for 0.01 μg of added mass. FIG. 9 depicts the simulated mass sensitivity of the resonating membrane where the response is linear and in agreement with Equation (3). FIG. 10 depicts the simulated mode shape of the membrane at the resonant frequency.

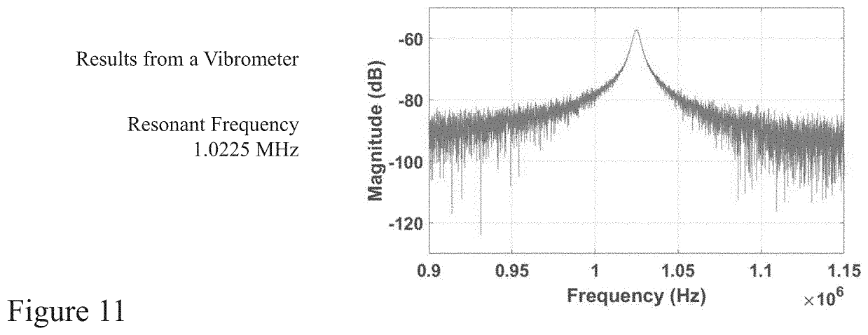

The fabricated die, third image 800D in FIG. 8B, of the test device were wire-bonded to an LCC-28 package, as depicted in fourth image 800E in FIG. 8B. The resonance characteristics of the device were measured using a vector network analyzer and a laser vibrometer showing consistent results. The results of the vibrometer measurements are shown in FIG. 11 depicting a resonance peak at 1.0225 MHz with a Q-factor of approximately 300.

In order to test the response of the MEMS resonator to a mass deposited on the resonating membrane the inventors employed incense sticks. Incense sticks are usually burnt during religious festivals and a major contributor of fine particulate matter, often smaller than 2.5 μm in size, see for example See et al. “Characterization of Fine Particle Emissions from Incense Burning” (Building and Environment, Vol. 46, pp. 1074-1080, 2011). The resonators in the LCC-28 package were soldered to a PCB which was placed face up inside a container. To imitate a particulate matter source, an approximately 15 cm (approximately 6 inch) long incense stick was burnt inside the container. Wires from the PCB were connected to a vector network analyzer (VNA) outside of the container through a hole drilled in one of the walls of the container. The burning of the incense stick led to the accumulation of particles inside the container, which gradually started to settle at the bottom of the container and onto the resonating membrane of the sensor. Due to continuous accumulation and settling of the particles on the resonating membrane, the inventors observed clear and continuous shifts in the resonant frequency. The incense stick burned continuously for 35 minutes and readings from the VNA were saved every 5 minutes.

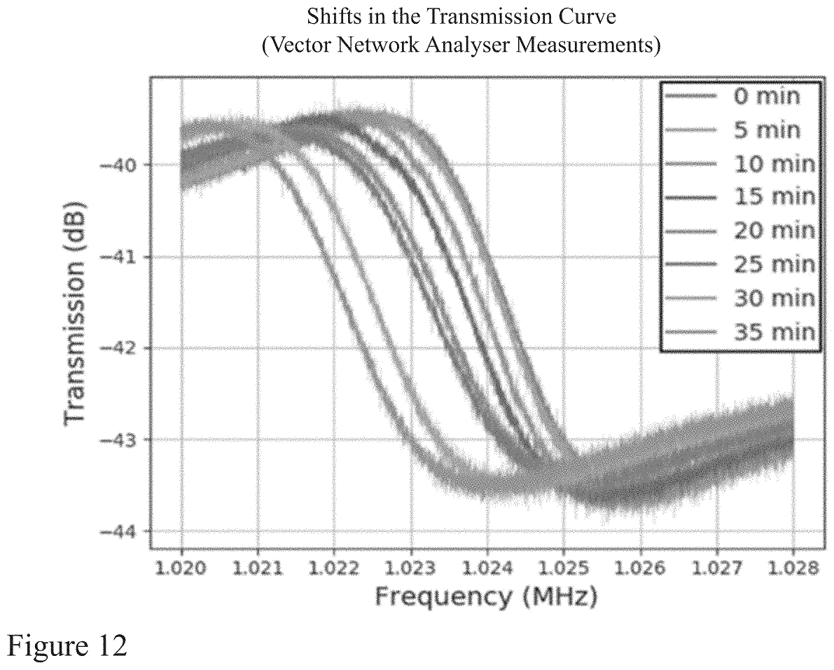

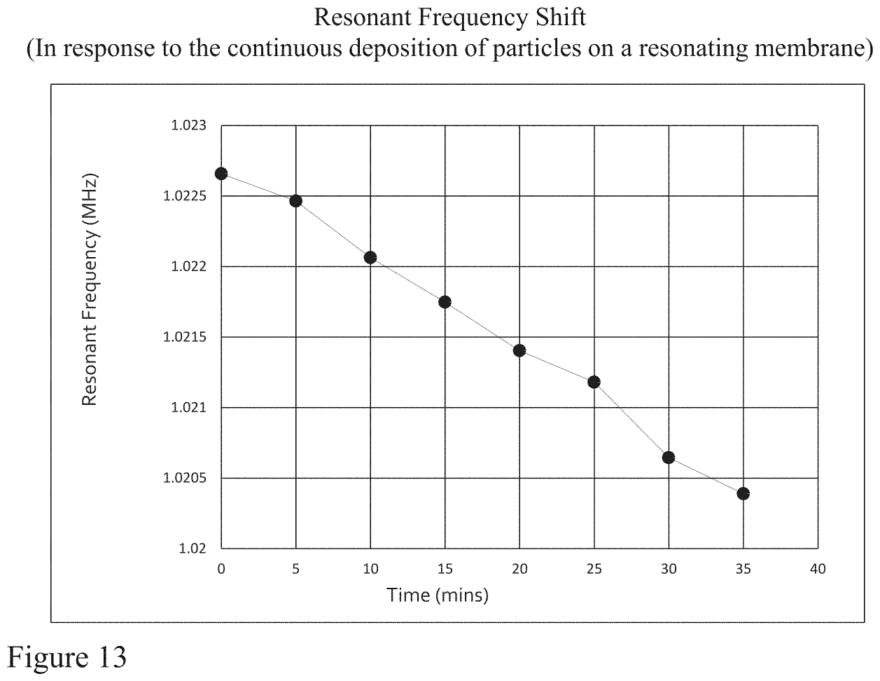

Referring to FIG. 12 there are depicted the resulting transmission S-parameter curves with respect to frequency taken at the different time intervals during the test indicated in FIG. 12. FIG. 13 depicts the resonant frequency of the MEMS resonator plotted against time. As evident the measured trend shows an almost linear response of the MEMS resonator to the mass of the deposited particles, which matches the simulations and theoretical results.

Accordingly, the inventors have demonstrated a piezoelectrically actuated resonating MEMS membrane as a detector of particulate matter in air. The tested device showed a clearly detectable shifts in the resonant frequency as the particles deposited on the MEMS resonator membrane. As described above this MEMS resonator may form part of a particulate matter sensing system consisting of a virtual impactor to direct the particle sizes of interest towards the sensor membrane in conjunction with a thermophoretic plate (or DEP electrodes) to direct the flow of particles towards and away from the sensing membrane. Accordingly, these MEMS resonators can be employed with highly-compact, low-cost, and accurate PDS devices etc. Such PDS can provide periodic or continuous monitoring against environmental regulations etc. such as the WHO PM limits on particulate exposure. Accordingly, the inventors believe that such PM sensors will allow for easy deployment of smart portable PDS devices for personal health monitoring etc.

Whilst the embodiments of the invention described and depicted with respect to FIGS. 1 to 13 have been described and depicted with respect to particulate/particle sensing within air it would be evident that the devices and methods described may be applied to particulate/particle sensing within other fluids including other gases or gas combinations as well as liquids. Whilst a MEMS resonator may suffer damping from a liquid, the shift in resonant frequency or electrical S-parameter may still be evident from the loading of particulates/particles deposited onto the membrane from the liquid.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A method of detecting particles comprising:
providing a microelectromechanical systems (MEMS) resonator comprising a membrane, an electrode atop the membrane and at least a pair of anchors;
exposing the MEMS resonator to a source of particles; and
determining in dependence upon a shift in a characteristic of the MEMS resonator a mass of particles deposited upon the membrane; wherein
the MEMS resonator is driven; and
a metal layer is patterned on top of the membrane to act as the top electrode, while the substrate acts as the bottom electrode (ground plane).

2. The method according to claim 1, further comprising
providing a piezoelectric layer between the membrane and the electrode; wherein
the MEMS resonator is piezoelectrically driven.

3. The method according to claim 1, wherein
the portion is defined by those particles being below a predetermined maximum dimension where the maximum predetermined dimension is established in dependence upon the dimensions of the virtual impactor.

4. The method according to claim 1, wherein
the source of particles is a portion of particles within a sampled source of air directed to the MEMS resonator by a virtual impactor structure; and
the portion is defined by those particles being below a predetermined maximum dimension.

5. The method according to claim 1, further comprising
providing a first plate comprising a first portion below the MEMS resonator and a second portion disposed upstream of the MEMS resonator; and
providing a second plate comprising at least a first portion above the MEMS resonator and a second portion disposed upstream of the MEMS resonator; wherein
the second plate is spaced away from the MEMS resonator by a predetermined distance;
in a first configuration the first plate has a temperature higher than the second plate;
in a second configuration the first plate has a temperature lower than the second plate;
the first plate and second plate in the first configuration adjust a relative direction of the particles relative to the surface of the membrane in a first direction; and
the first plate and second plate in the second configuration adjust the relative direction of the particles relative to the surface of the membrane in a second direction.

6. The method according to claim 1, further comprising
providing a first plate comprising a first portion below the MEMS resonator and a second portion disposed upstream of the MEMS resonator; and
providing a second plate comprising at least a first portion above the MEMS resonator and a second portion disposed upstream of the MEMS resonator; wherein
the second plate is spaced away from the MEMS resonator by a predetermined distance;
in a first configuration the first plate has an electrical potential higher than that of the second plate;
in a second configuration the first plate has an electrical potential lower than that of the second plate;
the first plate and second plate in the first configuration adjust a relative direction of the particles relative to the surface of the membrane in a first direction; and
the first plate and second plate in the second configuration adjust the relative direction of the particles relative to the surface of the membrane in a second direction.

7. A device comprising:
a filter for providing a source of particles having a predetermined maximum dimension;
a sensor comprising at least a microelectromechanical systems (MEMS) resonator; and
a first electrical circuit for driving the MEMS resonator; and
a second electrical circuit for determining a characteristic of the MEMS resonator.

8. The device according to claim 7, wherein
the microelectromechanical systems (MEMS) resonator comprising a membrane, a piezoelectric layer atop the membrane, an electrode atop the piezoelectric layer and at least a pair of anchors;
the MEMS resonator is piezoelectrically driven; and
a metal layer is patterned on top of the piezoelectric layer to act as the top electrode, while the substrate acts as the bottom electrode (ground plane).

9. The device according to claim 7, wherein
the filter is a virtual impactor structure;
the MEMS resonator and virtual impact structure are monolithically integrated upon a substrate; and
the maximum predetermined dimension can be varied by changing the dimensions of the virtual impactor.

10. The device according to claim 7, further comprising
a first plate comprising a first portion below the MEMS resonator and a second portion disposed upstream of the MEMS resonator; and
a second plate comprising at least a first portion above the MEMS resonator and a second portion disposed upstream of the MEMS resonator; wherein
the second plate is spaced away from the MEMS resonator by a predetermined distance;
in a first configuration the first plate has a temperature higher than the second plate;
in a second configuration the first plate has a temperature lower than the second plate;
the first plate and second plate in the first configuration adjust a relative direction of the particles relative to the surface of the membrane in a first direction; and
the first plate and second plate in the second configuration adjust the relative direction of the particles relative to the surface of the membrane in a second direction.

11. The device according to claim 7, further comprising
a first plate comprising a first portion below the MEMS resonator and a second portion disposed upstream of the MEMS resonator; and
a second plate comprising at least a first portion above the MEMS resonator and a second portion disposed upstream of the MEMS resonator; wherein
the second plate is spaced away from the MEMS resonator by a predetermined distance;
in a first configuration the first plate has an electrical potential higher than that of the second plate;
in a second configuration the first plate has an electrical potential lower than that of the second plate;
the first plate and second plate in the first configuration adjust a relative direction of the particles relative to the surface of the membrane in a first direction; and
the first plate and second plate in the second configuration adjust the relative direction of the particles relative to the surface of the membrane in a second direction.

12. The method according to claim 7, wherein
the characteristic of the MEMS resonator is either a shift in the resonant frequency or a shift in an electrical scattering parameter obtained from a signal coupled to the signal contact.

13. A method comprising:
providing a filter for providing a source of particles having a predetermined maximum dimension;
providing a sensor comprising at least a microelectromechanical systems (MEMS) resonator; and
providing a first electrical circuit for driving the MEMS resonator; and
providing a second electrical circuit for determining a characteristic of the MEMS resonator; wherein
the MEMS resonator employs a piezoelectric transduction mechanism or another transduction mechanism.

14. The method according to claim 13, further comprising
periodically resetting the sensor by clearing particles deposited upon the sensor from the sensor; wherein
clearing of particles deposited upon the sensor exploits a process based upon thermophoresis employing additional elements associated with the MEMS resonator.

15. The method according to claim 13, further comprising
periodically resetting the sensor by clearing particles deposited upon the sensor from the sensor; wherein
clearing of particles deposited upon the sensor exploits a process based upon thermophoresis independent of providing additional elements associated with the MEMS resonator.

16. The method according to claim 13, further comprising
periodically resetting the sensor by clearing particles deposited upon the sensor from the sensor; wherein
clearing of particles deposited upon the sensor exploits a process based upon di-electrophoresis employing additional elements associated with the MEMS resonator.

17. The method according to claim 13, wherein
another transduction mechanism of driving the MEMS resonator is capacitive based transduction; and
the characteristic of the MEMS resonator is determined from at least one of capacitance measurements and a shift if an electrical characteristic of the MEMS resonator.

18. The device according to claim 13, wherein
the MEMS resonator is a disc membrane based MEMS resonator.

19. The device according to claim 13, wherein the
the MEMS resonator is a beam based MEMS resonator.
